(19) United States
(12) Patent Application Publication
(10) Pub. No.: US 2014/0187679 A1
(43) Pub. Date: Jul. 3, 2014

(54) RESIN COMPOSITION WITH GOOD WORKABILITY, INSULATING FILM, AND PREPREG

(71) Applicant: SAMSUNG ELECTRO-MECHANICS CO., LTD., Suwon (KR)

(72) Inventors: Kwang Jik Lee, Suwon (KR); Joon Ho Bae, Suwon (KR); Hyun Chul Jung, Suwon (KR)

(73) Assignee: SAMSUNG ELECTRO-MECHANICS CO., LTD., Suwon (KR)

(21) Appl. No.: 13/831,678

(22) Filed: Mar. 15, 2013

(30) Foreign Application Priority Data
Dec. 28, 2012 (KR) 10-2012-0157126

(51) Int. Cl. H05K 1/03

(52) U.S. Cl. CPC H05K 1/0373
USPC 523/459

(57) ABSTRACT

This invention relates to a resin composition with good workability, including a liquid crystal oligomer, an epoxy resin, or a resin mixture thereof, and an inorganic filler having a nanocone shape, and to an insulating film for a printed circuit board, and a prepreg, which are manufactured using the resin composition.

### CROSS-REFERENCE TO RELATED APPLICATION

This application claims the benefit of Korean Patent Application No. 10-2012-0157126, filed Dec. 28, 2012, entitled “Resin composition with good workability, insulating film, and prepreg,” which is hereby incorporated by reference in its entirety into this application.

### BACKGROUND OF THE INVENTION

1. Technical Field

The present invention relates to a resin composition having good workability, an insulating film, and a prepreg.

2. Description of the Related Art

With the recent advancement of electronic devices and the increased demand for complicated functions thereof, printed circuit boards are being manufactured so as to be lighter, slimmer, and smaller. In order to fulfill such requirements, printed circuit wiring has become more complicated and even denser, and its functionality has increased.

As electronic devices are being manufactured so as to be small and to have high functionality, as mentioned above, a multilayer printed circuit board is required, which has high density and high functionality, as well as being small and slim. In particular, a multilayer printed circuit board is required that incorporates wiring that is fine and dense. Accordingly, thermal, mechanical and electrical properties of an insulating layer of the multilayer printed circuit board are considered important. Particularly, in order to minimize warpage due to reflow in the course of mounting an electronic/electrical device, the device has to have a low coefficient of thermal expansion (CTE), a high glass transition temperature (Tg), and high modulus.

An insulating substrate for a printed circuit board is typically exemplified by a copper clad laminate (CCL) obtained by adding a binder to reinforced glass fibers, drying it, thus obtaining a prepreg, laminating a predetermined number of prepregs, and layering a copper foil thereon. The prepreg is formed by impregnating glass fibers with a cross-linkable resin such as epoxy. However, in the case of the prepreg manufactured by the above method using general glass fibers, it is common to encounter problems such as deformation and disconnection due to high CTE, making it impossible to develop a high value-added prepreg.

Although a printed circuit board typically functions to connect a variety of electronic parts to a printed-circuit base board, depending on the circuit design of electrical wiring thereof, or to support the parts, power consumption of the parts is increased and a large quantity of heat is generated in proportion to an increase in the number of mounted passive parts and packages, and thus heat-releasing performance is regarded as important in terms of reliability of products and consumers' product preferences.

Meanwhile, in the case of the conventional prepreg and CCL, an insulating material is prepared by filling a resin layer such as epoxy, polyimide, or aromatic polyester with a ceramic filler such as silica, alumina, etc., but the effects thereof are not sufficient. The conventional prepreg and CCL are limited in reducing warpage of a thin substrate. For example, Patent Literature 1 discloses an epoxy resin composition including a liquid crystal oligomer, but this patent is problematic because a network between the inorganic filler and the polymer resin is not sufficiently formed, CTE is not sufficiently decreased to the level required for a printed circuit board, and Tg is not sufficiently increased. Moreover, when the filling rate of the inorganic filler is increased, viscosity of the main resin may increase, undesirably deteriorating workability.

Patent Literature 1: Korean Unexamined Patent Publication No. 2011-0108198

### SUMMARY OF THE INVENTION

Culminating in the present invention, intensive and thorough research with the aim of solving the problems occurring in the related art resulted in the finding that the addition of an inorganic filler having a nanocone shape may increase thermal and mechanical properties of an insulating material while maintaining workability thereof.

Accordingly, a first aspect of the present invention is to provide a resin composition, which may have good workability, as well as superior heat resistance and mechanical strength.

A second aspect of the present invention is to provide an insulating film for a printed circuit board, which may be manufactured using the resin composition so as to exhibit low CTE and good workability.

A third aspect of the present invention is to provide a prepreg for a printed circuit board, manufactured by impregnating a base material such as woven glass fibers with the resin composition.

In order to accomplish the above first aspect of the present invention, a resin composition having good workability (hereinafter, referred to as “the first invention”) is provided, which includes a liquid crystal oligomer, an epoxy resin, or a resin mixture thereof; and an inorganic filler having a nanocone shape.

In the first invention, the liquid crystal oligomer may be represented by Chemical Formula 1, 2, 3, or 4 below.

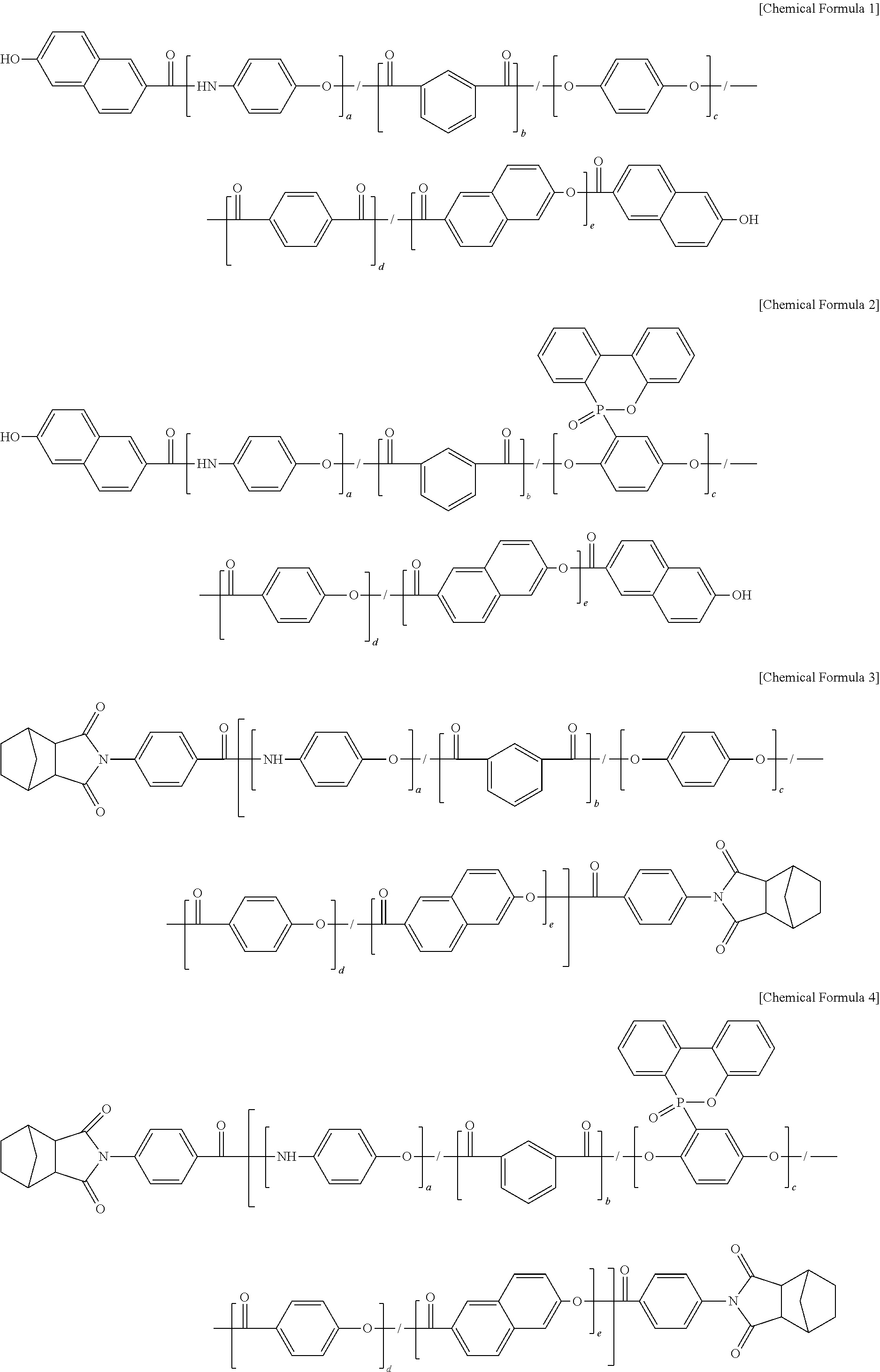

wherein a is an integer of 13˜26, b is an integer of 13˜26, c is an integer of 9˜21, d is an integer of 10˜30, and e is an integer of 10˜30.

In the first invention, the epoxy resin may be represented by Chemical Formula 5 or 6 below.

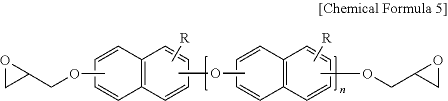

wherein R is an alkyl group having 1˜20 carbons, and n is an integer of 0˜20.

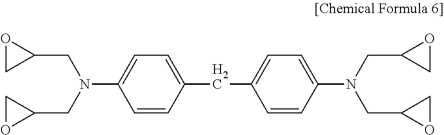 [SMILES: c1cc(N(CC2CO2)CC2CO2)ccc1Cc1ccc(N(CC2CO2)CC2CO2)cc1]

In the first invention, the resin composition may include 5˜90 wt % of the liquid crystal oligomer, 5˜90 wt % of the epoxy resin, or 5˜90 wt % of the resin mixture comprising 0.5˜50 wt % of the liquid crystal oligomer and 5˜50 wt % of the epoxy resin, and 10˜95 wt % of the filler.

In the first invention, the liquid crystal oligomer may have a number average molecular weight of 2,500˜6,500.

In the first invention, the epoxy resin may include one or more selected from the group consisting of a naphthalenic epoxy resin, a bisphenol A type epoxy resin, a phenol novolac epoxy resin, a cresol novolac epoxy resin, a rubber modified epoxy resin, and a phosphorous epoxy resin.

In the first invention, the inorganic filler may include one or more selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

In the first invention, the inorganic filler may further include a component comprising one or more selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate, all of which have a shape different from the nanocone shape.

In the first invention, the inorganic filler having the nanocone shape may be used in an amount of 5 wt % or more based on the total weight of the inorganic filler.

In the first invention, the nanocone shape may be a shape having different upper and lower cross-sectional areas or a conical shape.

In the first invention, the resin composition may further include a thermoplastic resin comprising one or more selected from the group consisting of a phenoxy resin, a polyimide resin, a polyamideimide (PM) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, and a polyester resin.

In order to accomplish the above second aspect of the present invention, an insulating film for a printed circuit board is provided, which is manufactured using the resin composition according to the first invention.

In order to accomplish the above third aspect of the present invention, a prepreg for a printed circuit board is provided, which is manufactured by impregnating a base material with the resin composition according to the first invention.

### BRIEF DESCRIPTION OF THE DRAWINGS

The above and other aspects, features and other advantages of the present invention will be more clearly understood from the following detailed description when taken in conjunction with the accompanying drawings, in which:

FIG. 1 is a cross-sectional view illustrating a typical printed circuit board to which a resin composition according to the present invention may be applied;

FIG. 2 is of schematic views illustrating examples of a nanocone shape formed using a typical nanorod; and

FIG. 3 is an electron microscope image of an inorganic additive (zinc oxide) having a nanocone shape, used in the present invention.

### DESCRIPTION OF SPECIFIC EMBODIMENTS

Before the present invention is described in more detail, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention. It is noted that, the embodiments of the present invention are merely illustrative, and are not construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related with the present invention may make the gist of the present invention unclear, a detailed description thereof will be omitted.

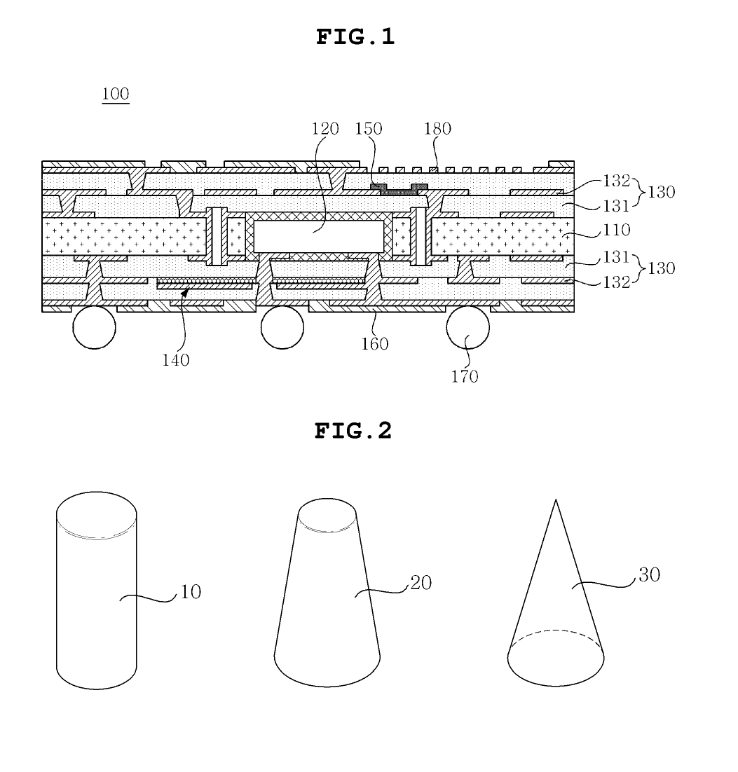

FIG. 1 is a cross-sectional view illustrating a typical printed circuit board to which a resin composition according to the present invention may be applied. As illustrated in FIG. 1, a printed circuit board 100 may be an embedded board including electronic parts therein. Specifically, the printed circuit board 100 may include an insulator or prepreg 110 having a cavity, an electronic part 120 provided in the cavity, and build-up layers 130 formed on one or more of the upper and lower surfaces of the insulator or prepreg 110 including the electronic part 120. The build-up layers 130 may include insulating layers 131 formed on one or more of the upper and lower surfaces of the insulator 110, and circuit layers 132 which are formed on the insulating layers 131 and may achieve interlayer connection.

An example of the electronic part 120 may include an active device such as a semiconductor device. Also, the printed circuit board 100 may further include one or more additional electronic parts, for example, a capacitor 140, a resistor 150, etc., in addition to the single electronic part 120. In embodiments of the present invention, the kind or number of the electronic parts is not limited. As such, the insulator or prepreg 110 and the insulating layers 131 play a role in imparting insulating properties between the circuit layers or between the electronic parts, and also function as a support for maintaining rigidity of a package.

In the case where the wiring density of the printed circuit board 100 is increased, to decrease noise between the circuit layers and also to reduce parasitic capacitance, the insulator or prepreg 110 and the insulating layers 131 should have low dielectric properties. Furthermore, the insulator or prepreg 110 and the insulating layers 131 should have low dielectric loss to increase insulating properties.

At least any one of the insulator or prepreg 110 and the insulating layers 131 is particularly useful so long as it is superior in terms of heat resistance, such as CTE, and mechanical strength, and has good workability, due to a high filling rate of a filler.

In the present invention, in order to reduce CTE of the insulating layers and increase Tg to ensure rigidity and improve workability (e.g. viscosity), the insulating layers or the prepreg may be formed from a resin composition including a liquid crystal oligomer, an epoxy resin or resin mixtures thereof, and an inorganic filler having a nanocone shape.

Liquid Crystal Oligomer

In the present invention, a liquid crystal oligomer, and particularly, a liquid crystal oligomer represented by Chemical Formulas 1 to 4 below may include an ester group at both terminals of the main chain thereof to improve dielectric tangent and dielectric constant, and a naphthalene group to ensure desired crystallinity, and may contain a phosphorus component for imparting fire retardancy as shown in Chemical Formula 2 or 4. More specifically, the liquid crystal oligomer includes a hydroxyl group or a nadimide group at the terminals thereof, so that it may be subjected to a thermosetting reaction with an epoxy resin.

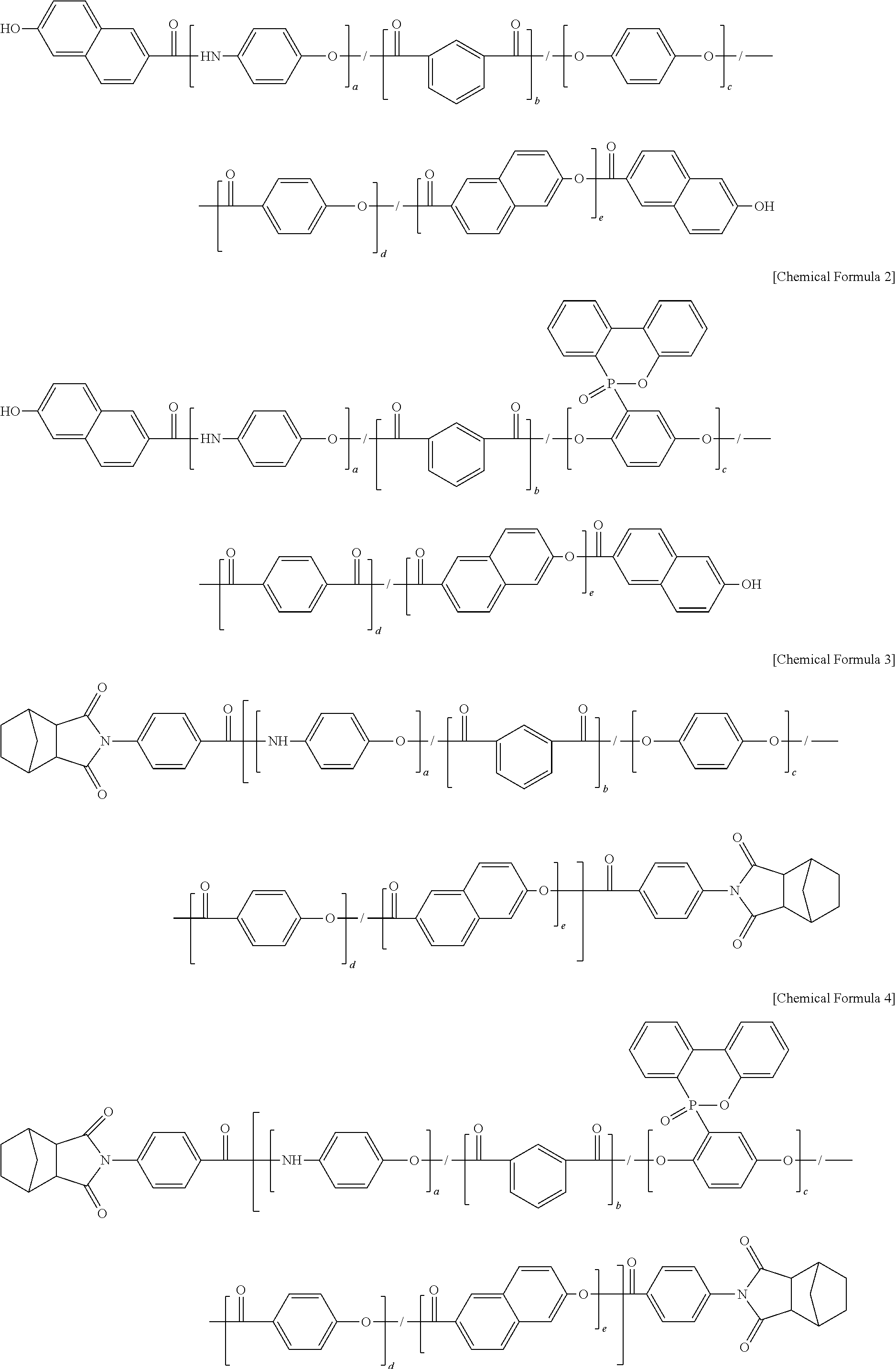

In Chemical Formulas 1 to 4, a is an integer of 13˜26, b is an integer of 13˜26, c is an integer of 9˜21, d is an integer of 10˜30, and e is an integer of 10˜30.

The number average molecular weight of the liquid crystal oligomer is 2,500˜6,500 g/mol, preferably 3,000˜6,000 g/mol, and more preferably 4,500˜5,500 g/mol. If the number average molecular weight of the liquid crystal oligomer is less than 2,500 g/mol, mechanical properties may deteriorate. In contrast, if the number average molecular weight thereof exceeds 6,500 g/mol, solubility may decrease.

The liquid crystal oligomer may be used in an amount of 5˜90 wt %, and the amount thereof may be set to 0.5˜50 wt % when used together with the epoxy resin. If the amount of the liquid crystal oligomer is less than 0.5 wt %, CTE may decrease and an increase in Tg may become insignificant. In contrast, if the amount thereof exceeds 90 wt %, thermal properties, such as CTE, and mechanical properties may deteriorate.

Epoxy Resin

According to the present invention, the resin composition includes the epoxy resin in order to increase handleability of the dried resin composition as an adhesive film. The epoxy resin is not particularly limited, but indicates a resin including one or more epoxy groups, preferably two or more epoxy groups, and more preferably four or more epoxy groups, in the molecule thereof.

The epoxy resin used in the present invention may be a compound containing a naphthalene group as represented by Chemical Formula 5 below, or an aromatic amine as represented by Chemical Formula 6 below.

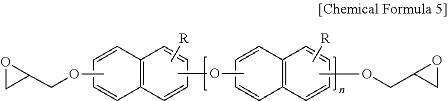

In Chemical Formula 5, R is an alkyl group having 1˜20 carbons, and n is an integer of 0˜20.

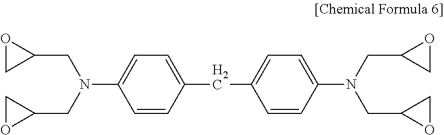 [SMILES: c1cc(N(CC2CO2)CC2CO2)ccc1Cc1ccc(N(CC2CO2)CC2CO2)cc1]

However, the epoxy resin used in the present invention is not particularly limited to the epoxy resin represented by Chemical Formula 5 or 6, and may include, for example, bisphenol A type epoxy resin, bisphenol F type epoxy resin, bisphenol S type epoxy resin, phenol novolac epoxy resin, alkylphenol novolac epoxy resin, biphenyl type epoxy resin, aralkyl type epoxy resin, dicyclopentadiene type epoxy resin, naphthalenic epoxy resin, naphthol type epoxy resin, epoxy resin including a condensate of phenol and aromatic aldehyde having a phenolic hydroxyl group, biphenylaralkyl type epoxy resin, fluorene type epoxy resin, xantene type epoxy resin, triglycidyl isocyanurate, rubber modified epoxy resin and phosphorous epoxy resin. Particularly useful is naphthalenic epoxy resin, bisphenol A type epoxy resin, phenol novolac epoxy resin, cresol novolac epoxy resin, rubber modified epoxy resin, or phosphorous epoxy resin. These epoxy resins may be used alone or in combination of two or more.

The epoxy resin may be used in an amount of 5˜90 wt %, and the amount thereof is set to 4˜50 wt % when used together with the liquid crystal oligomer. If the amount of the epoxy resin is less than 4 wt %, handleability or workability may decrease. In contrast, if the amount thereof exceeds 90 wt %, the amounts of the other components may be comparatively decreased, undesirably lowering dielectric tangent, dielectric constant, and CTE.

Inorganic Filler

The resin composition according to the present invention includes an inorganic filler to decrease CTE of the epoxy resin and improve heat-releasing properties without decreasing handleability or workability. The amount of the filler in the resin composition may be set to 10˜95 wt %, depending on the required properties taking into consideration the end uses of the resin composition. If the amount of the filler is less than 10 wt %, dielectric tangent may decrease and CTE may increase, and there is almost no improvement in heat-releasing properties. In contrast, if the amount thereof exceeds 95 wt %, viscosity may increase, undesirably decreasing workability and deteriorating adhesive strength and mechanical properties.

In the present invention, the inorganic filler has a nanocone shape. As illustrated in FIG. 2, the nanocone is provided in the form of a nanowire 10, the upper and lower cross-sectional areas of which being similar or identical to each other, a truncated cone 20 having different upper and lower cross-sectional areas via simple surface treatment of the nanowire, or a cone 30.

The inorganic filler having such a nanocone shape may be prepared using chemical vapor deposition (Zhang, Z.; Yuan, H.; Zhou, J.; Liu, D.; Luo, S.; Miao, Y.; Gao, Y.; Wang, J.; Liu, L.; Song, L.; Xiang, Y.; Zhao, X.; Zhou, W.; Xie, S. Journal of Physical Chemistry B 2006, 110, 8566), metallic organic chemical deposition (Yang, J. L.; An, S. J.; Park, W. I.; Yi, G. C.; Choi, W. Advanced Materials 2004, 16, 1661), hydrothermal synthesis (Chang, Y. C.; Chen, L. J. Journal of Physical Chemistry C 2007, 111, 1268), pulse laser deposition (Chen, J. J.; Yu, M. H.; Zhou, W. L.; Sun, K.; Wang, L. M. Applied Physics Letters 2005, 87), etc. Also, Korean Unexamined Patent Publication No. 2010-0087598 discloses a method of manufacturing a zinc oxide nanocone via chemical etching in an aqueous hydrochloric acid solution, including forming a zinc oxide nanowire or nanorod on a substrate; and immersing the substrate having the zinc oxide nanowire or nanorod in an aqueous hydrochloric acid solution, which is hereby incorporated by reference into the present invention.

On the other hand, the inorganic filler according to the present invention may include one or more selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate. For example, in order to ensure heat-releasing properties of a film made of the resin composition, boron nitride or aluminum borate having a nanocone shape may be used, and to ensure mechanical properties of a film, silica is useful.

Also, the inorganic filler according to the present invention may further include an inorganic filler component comprising one or more selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate, all of which have a shape (e.g. a circular shape, a rod shape, a wire shape in cross-section) different from the nanocone shape.

In this case, although the amount of the inorganic filler in the resin composition may vary depending on the required properties in consideration of the end uses of the resin composition, the inorganic filler having a nanocone shape may be used in an amount of 5 wt % or more in the addition range (i.e. 10˜95 wt %) of the inorganic filler, in order to attain desired workability.

Furthermore, in the case where the average particle size of the inorganic filler having a different shape exceeds 5 μm, it is difficult to stably form a fine pattern upon forming a circuit pattern on a conductor layer. Hence, the average particle size thereof is set to 5 μm or less. In order to increase moisture resistance, the inorganic filler may be surface-treated with a surface treating agent such as a silane coupling agent, etc. Particularly useful is silica having a diameter of 0.2˜2 μm.

Curing Agent

In the present invention, a curing agent may be optionally used, and any one may be used without particular limitation so long as it enables thermosetting of an epoxy resin.

Specific examples of the curing agent may include an amide-based curing agent such as dicyandiamide; a polyamine-based curing agent, including diethylenetriamine, triethylenetetramine, N-aminoethylpiperazine, diaminodiphenylmethane, adipic acid dihydrazide, etc.; an acid anhydride curing agent, including pyromellitic anhydride, benzophenone tetracarboxylic anhydride, ethylene glycol bis trimellitic anhydride, glycerol tris trimellitic anhydride, maleic methylcyclohexene tetracarboxylic anhydride, etc.; a phenol novolac type curing agent; a polymercaptan curing agent, such as trioxane trimethylene mercaptan, etc.; a tertiary amine curing agent, including benzyldimethylamine, 2,4,6-tris(dimethylaminomethyl)phenol, etc.; and an imidazole curing agent, including 2-ethyl-4-methyl imidazole, 2-methyl imidazole, 1-benzyl-2-methyl imidazole, 2-heptadecyl imidazole, 2-undecyl imidazole, 2-phenyl-4-methyl-5-hydroxymethyl imidazole, 2-phenyl imidazole, 2-phenyl-4-methyl imidazole, 1-benzyl-2-phenyl imidazole, 1,2-dimethyl imidazole, 1-cyanoethyl-2-phenyl imidazole, and 2-phenyl-4,5-dihydroxymethyl imidazole. These curing agents may be used alone or in combination of two or more. In order to obtain desired properties, dicyandiamide is preferably used. The amount of the curing agent may be appropriately determined in the range known well to those skilled in the art, for example, in the range of 0.1˜1 parts by weight, based on 100 parts by weight of the mixture of liquid crystal oligomer and epoxy resin, taking into consideration the curing rate without deteriorating inherent properties of the epoxy resin.

Curing Accelerator

The resin composition of the present invention may optionally include a curing accelerator, and thereby may be efficiently cured. The curing accelerator used in the present invention may include a metallic curing accelerator, an imidazole-based curing accelerator, an amine-based curing accelerator, etc., which may be used alone or in combination of two or more in an amount typically used in the art.

Examples of the metallic curing accelerator include, but are not particularly to, organic metal complexes or organic metal salts of metal such as cobalt, copper, zinc, iron, nickel, manganese, tin, etc. Specific examples of the organic metal complex include an organic cobalt complex, including cobalt (II) acetylacetonate, cobalt (III) acetylacetonate, etc., an organic copper complex, such as copper (II) acetylacetonate, etc., an organic zinc complex, such as zinc (II) acetylacetonate or the like, an organic iron complex, such as iron (III) acetylacetonate or the like, an organic nickel complex, such as nickel (II) acetylacetonate or the like, an organic manganese complex, such as manganese (II) acetylacetonate, etc. Examples of the organic metal salt include zinc octylate, tin octylate, zinc naphthenate, cobalt naphthenate, tin sterate, zinc stearate, etc. From the point of view of curability and solubility in solvent, cobalt (II) acetylacetonate, cobalt (III) acetylacetonate, zinc (II) acetylacetonate, zinc naphthenate, or iron (III) acetylacetonate may be used as the metallic curing accelerator. Particularly useful is cobalt (II) acetylacetonate or zinc naphthenate. These metallic curing accelerators may be used alone or in combination of two or more.

The imidazole-based curing accelerator is not particularly limited, but examples thereof may include imidazole compounds, including 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanurate adducts, 2-phenylimidazole isocyanurate adducts, 2-phenyl-4,5-dihydroxy-methylimidazole, 2-phenyl-4-methyl-5-hydroxymethylimidazole, 2,3-dihydroxy-1H-pyro[1,2-a]benzimidazole, 1 -dodecyl-2-methyl-3-benzylimidazolium chloride, 2-methylimidazoline, 2-phenylimidazoline, etc., and adducts of imidazole compound and epoxy resin. These imidazole curing accelerators may be used alone or in combination of two or more.

The amine-based curing accelerator is not particularly limited, but examples thereof may include trialkylamines, including triethylamine, tributylamine, etc., and amine compounds, including 4-dimethylaminopyridine, benzyldimethylamine, 2,4,6-tris(dimethylaminomethyl)phenol, 1,8-diazabicyclo(5,4,0)-undecene, etc. The amine-based curing accelerators may be used alone or in combination of two or more.

Thermoplastic Resin

The resin composition of the present invention may optically include a thermoplastic resin to improve film properties of a resin composition or to improve mechanical properties of a cured product. Examples of the thermoplastic resin include phenoxy resin, polyimide resin, polyamideimide (PAI) resin, polyetherimide (PEI) resin, polysulfone (PS) resin, polyethersulfone (PES) resin, polyphenyleneether (PPE) resin, polycarbonate (PC) resin, polyetheretherketone (PEEK) resin, polyester resin, etc. These thermoplastic resins may be used alone or in combination of two or more. The weight average molecular weight of the thermoplastic resin falls in the range of 5,000˜200,000. If the weight average molecular weight thereof is less than 5,000, improvements in film formability or mechanical strength become insignificant. In contrast, if the weight average molecular weight thereof exceeds 200,000, compatibility with the liquid crystal oligomer and the epoxy resin becomes poor, and surface roughness may increase after a curing process, making it difficult to form a high-density fine pattern. The weight average molecular weight was calculated based on the calibration curve of standard polystyrene at a column temperature of 40° C. using LC-9A/RID-6A as a measuring device available from Shimadzu Corporation, Shodex K-800P/K-804L/K-804L as a column available from Showa Denko, and chloroform (CHCl₃) as a mobile phase.

In the case where the thermoplastic resin is added to the resin composition, the amount of the thermoplastic resin in the resin composition is not particularly limited but may be set to 0.1˜10 wt %, and preferably 1˜5 wt %, based on 100 wt % of nonvolatile content of the resin composition. If the amount of the thermoplastic resin is less than 0.1 wt %, there is no improvement in film formability or mechanical strength. In contrast, if the amount thereof exceeds 10 wt %, melting viscosity may increase and the surface roughness of the insulating layer after a wet roughening process may increase.

The insulating resin composition according to the present invention is prepared in the presence of an organic solvent. Taking into consideration solubility and miscibility of the resin and other additives used in the present invention, examples of the organic solvent may include, but are not particularly limited to, 2-methoxy ethanol, acetone, methylethylketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethylformamide, and dimethylacetamide.

The viscosity of the resin composition according to the present invention is 700˜1500 cps which is adapted to manufacture an insulating film, and this viscosity corresponds to the extent to which appropriate stickiness may be maintained at room temperature. The viscosity of the resin composition may be adjusted by changing the amount of the solvent. The nonvolatile content (solid content) of the resin composition, excluding the solvent, may be 30˜70 wt %. If the viscosity of the resin composition falls outside of the above range, it is difficult to form an insulating film. Even when such a film is formed, it is difficult to form a predetermined member thereon.

Also, peel strength may be 1.0 kN/m or more when a copper foil 12 μm thick is used on the insulating film. The insulating film manufactured using the resin composition according to the present invention has a CIE of 20 ppm/° C. or less. Furthermore, Tg may be 200˜300° C., and preferably 250˜270° C.

In addition, the resin composition according to the present invention may further include a leveling agent and/or a fire retardant, as necessary, provided by those skilled in the art within the scope of the present invention.

The insulating resin composition according to the present invention may be manufactured in the form of a dry film in a semi-solid phase using any process typically known in the art. For example, the resin composition may be formed into a film using a roll coater or a curtain coater and then dried, after which the resulting film is used as an insulating layer (or an insulating film) or a prepreg upon manufacturing a multilayer printed circuit board using a building-up process on a substrate. Such an insulating film or prepreg has a low CTE of 50 ppm/° C. or less.

A base material such as glass fibers is impregnated with the resin composition according to the present invention, and then cured, thus preparing a prepreg, on which a copper foil is then laminated, thereby obtaining CCL (Copper Clad Laminate). Also, the insulating film formed from the above resin composition may be laminated on the CCL used as an inner layer upon manufacturing a multilayer printed circuit board. For example, an insulating film made of the insulating resin composition may be laminated on an inner circuit board having a processed pattern, cured at 80˜110° C. for 20˜30 min, and subjected to desmearing, followed by performing an electroplating process, thus forming a circuit layer, resulting in a multilayer printed circuit board.

A better understanding of the present invention may be obtained via the following examples and comparative examples which are set forth to illustrate, but are not to be construed as limiting the present invention.

### PREPARATION EXAMPLE 1

(1) Zinc Oxide Nanorod

A p type silicon wafer was cut to a size of 1 cm×1 cm and then treated for 2 min in an aqueous hydrofluoric acid solution to remove silicon oxide from the wafer. The oxide-free silicon wafer was placed on the water surface of a beaker containing the aqueous solution of zinc nitrate hexahydrate (15 mM) and hexamethylenetetramine (15 mM) so that its surface was turned over. The aqueous solution was maintained at 93° C., and the total reaction time was 6 hr. Thereafter, the wafer was taken out of the aqueous solution, rinsed with water, and dried in air at 80° C. for 1 hr, thus manufacturing a zinc oxide nanorod (10 in FIG. 2).

(2) Zinc Oxide Nanocone

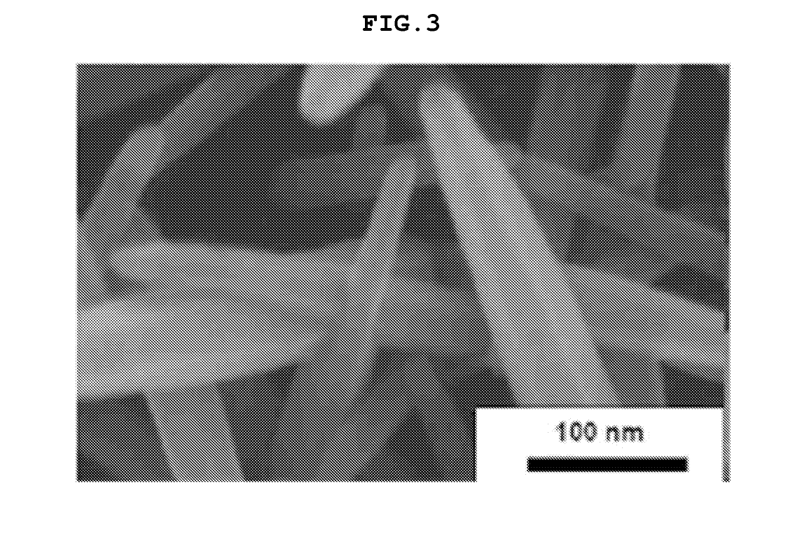

The wafer having the zinc oxide nanorod was immersed in an aqueous hydrochloric acid solution having pH of 3 at room temperature, stirred for 30 min, and subjected to wet chemical etching. The wafer was removed from the aqueous hydrochloric acid solution, rinsed and then dried, thus obtaining a zinc oxide nanocone. The zinc oxide nanocone was observed using a scanning electron microscope. The results are given in FIG. 3.

### EXAMPLE 1

Each of the zinc oxide nanorod and the zinc oxide nanocone of Preparation Example 1 in the amount shown in Table 1 below was mixed with 65 wt % of silica having an average diameter of 0.2˜1 μm in methylethylketone, and then added to an epoxy resin, Araldite MY-721 (Huntsmann), thus preparing a varnish. The varnish was applied to a thickness of 100 μm on the shiny surface of a copper foil using a doctor blade process, thus manufacturing a film. The film was dried at room temperature for 2 hr, dried in a vacuum oven at 80° C. for 1 hr, and then further dried at 110° C. for 1 hr, thus obtaining a semi-cured state (B-stage). This film was completely cured using a vacuum press. As such, the maximum temperature was 230° C. and the maximum pressure was 2 MPa. The CTE, Tg, and viscosity of the film were measured. The results are shown in Table 1 below.

Measurement of Thermal Properties

The CTE of the test sample of Example 1 was measured using a thermomechanical analyzer (TMA), and Tg thereof was measured in the range to 270° C. (1^{st} cycle), 300° C. (2^{nd} cycle) at a heating rate of 10° C./min in a nitrogen atmosphere using a thermomechanical analyzer (TA Instruments TMA 2940) by differential scanning calorimetry (DSC).

Measurement of Viscosity

The viscosity of the test sample of Example 1 was measured using a Brookfield viscometer.

TABLE 1

| | CTE (ppm/° C.) | | Tg (° C.) | | Viscosity (cps) | |
|---|---|---|---|---|---|---|
| | Nanorod | Nanocone | Nanorod | Nanocone | Nanorod | Nanocone |
| 5 wt % addition | 25 | 21 | 147 | 145 | 3800 | 3500 |
| (Total inorganic | | | | | | |
| additive: 70 wt %) | | | | | | |
| 10 wt % addition | 21 | 17 | 145 | 143 | 4200 | 4010 |
| (Total inorganic | | | | | | |
| additive: 75 wt %) | | | | | | |
| 15 wt % addition | 17 | 13 | 143 | 141 | 4700 | 4450 |
| (Total inorganic | | | | | | |
| additive: 80 wt %) | | | | | | |
| 20 wt % addition | 14 | 11 | 140 | 138 | 5210 | 5010 |
| (Total inorganic | | | | | | |
| additive: 85 wt %) | | | | | | |
| 25 wt % addition | 11 | 10 | 139 | 137 | 5700 | 5500 |
| (Total inorganic | | | | | | |
| additive: 90 wt %) | | | | | | |

As is apparent from Table 1, the epoxy resin including the inorganic filler having a nanocone shape according to the present invention exhibited lower viscosity, compared to the epoxy resin including the same amount of the inorganic filler having a nanorod shape, and thus superior workability was obtained. This means that a larger amount of inorganic filler may be added, ultimately improving thermal properties of a film made of the resin, including low CTE and superior heat-releasing properties.

As described hereinbefore, the present invention provides a resin composition with good workability, an insulating film, and a prepreg. According to the present invention, the resin composition including an inorganic filler having a nanocone shape has a higher filling rate, compared to when using resin including an inorganic additive having a different shape in the same amount as in the above inorganic filler. Thus, when a film is manufactured using the resin composition, superior heat resistance and mechanical strength can be exhibited, and also, good workability can be obtained thanks to low viscosity.

Although the embodiments of the present invention have been disclosed for illustrative purposes, those skilled in the art will appreciate that a variety of different modifications, additions and substitutions are possible, without departing from the scope and spirit of the invention as disclosed in the accompanying claims.

Accordingly, such modifications, additions and substitutions should also be understood as falling within the scope of the present invention.

What is claimed is:

1. A resin composition having good workability, comprising:
a liquid crystal oligomer, an epoxy resin, or a resin mixture thereof, and
an inorganic filler having a nanocone shape.

2. The resin composition of claim 1, wherein the liquid crystal oligomer is represented by Chemical Formula 1, 2, 3, or 4 below. 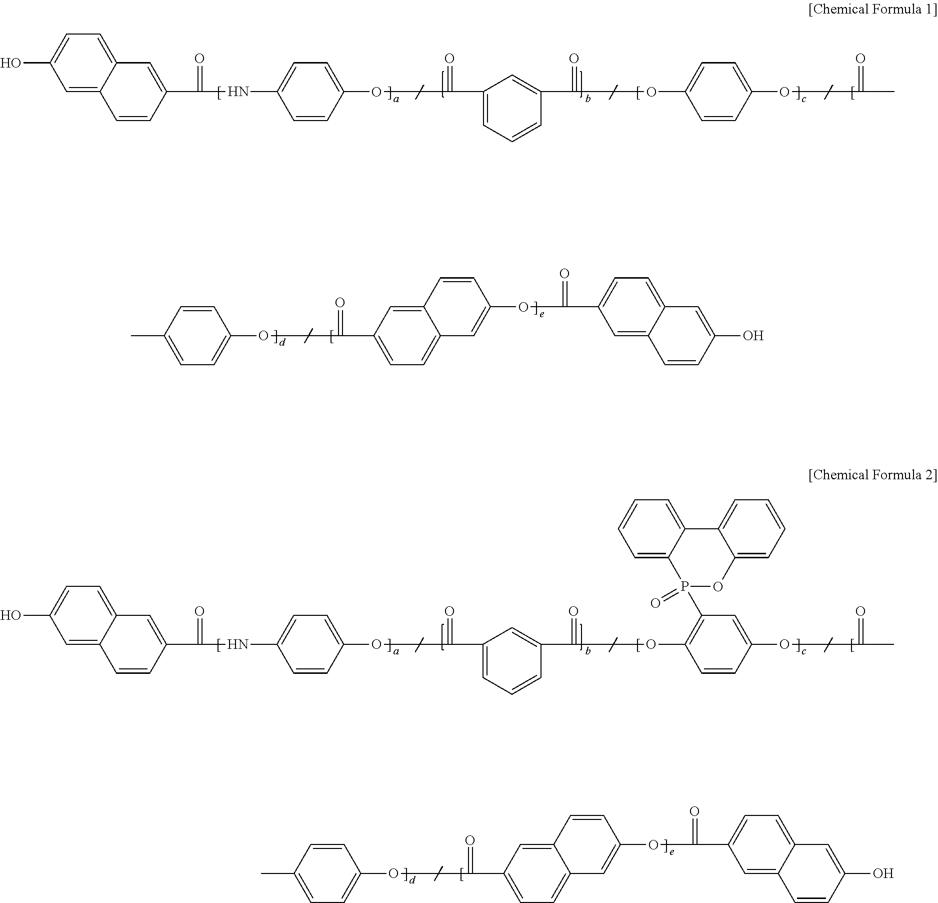 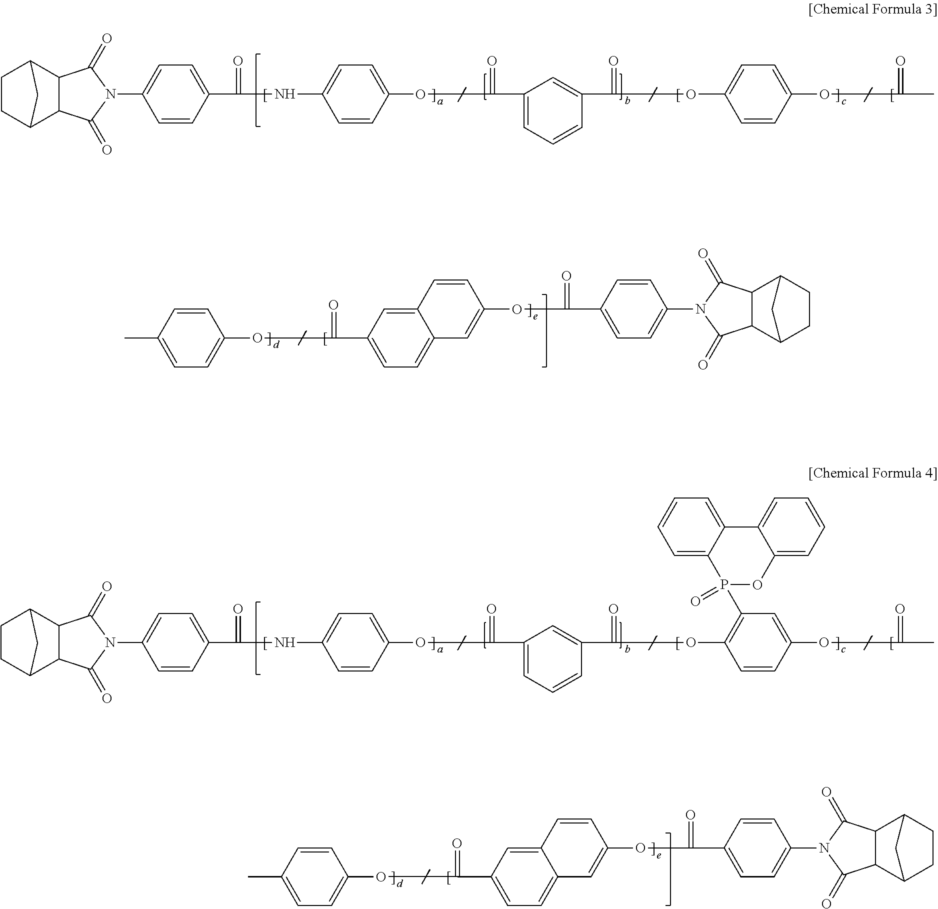
wherein a is an integer of 13˜26, b is an integer of 13˜26, c is an integer of 9˜21, d is an integer of 10˜30, and e is an integer of 10˜30.

3. The resin composition of claim 1, wherein the epoxy resin is represented by Chemical Formula 5 or 6 below. 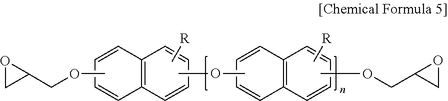
wherein R is an alkyl group having 1˜20 carbons, and n is an integer of 0˜20.

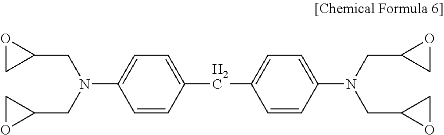 [SMILES: c1cc(N(CC2CO2)CC2CO2)ccc1Cc1ccc(N(CC2CO2)CC2CO2)cc1]

4. The resin composition of claim 1, wherein the resin composition comprises 5˜90 wt % of the liquid crystal oligomer, 5˜90 wt % of the epoxy resin, or 5˜90 wt % of the resin mixture comprising 0.5˜50 wt % of the liquid crystal oligomer and 5. 50 wt % of the epoxy resin, and 10˜95 wt % of the inorganic filler.

5. The resin composition of claim 1, wherein the liquid crystal oligomer has a number average molecular weight of 2,500˜6,500.

6. The resin composition of claim 1, wherein the epoxy resin comprises one or more selected from the group consisting of a naphthalenic epoxy resin, a bisphenol A type epoxy resin, a phenol novolac epoxy resin, a cresol novolac epoxy resin, a rubber modified epoxy resin, and a phosphorous epoxy resin.

7. The resin composition of claim 1, wherein the inorganic filler comprises one or more selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

8. The resin composition of claim 1, wherein the inorganic filler further includes a component comprising one or more selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate, all of which have a shape different from the nanocone shape.

9. The resin composition of claim 1, wherein the inorganic filler having the nanocone shape is used in an amount of 5 wt % or more based on a total weight of the inorganic filler.

10. The resin composition of claim 1, wherein the nanocone shape is a shape having different upper and lower cross-sectional areas or a conical shape.

11. The resin composition of claim 1, further comprising a thermoplastic resin comprising one or more selected from the group consisting of a phenoxy resin, a polyimide resin, a polyamideimide (PAI) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, and a polyester resin.

12. An insulating film for a printed circuit board, manufactured using the resin composition of claim 1.

13. A prepreg, manufactured by impregnating a base material with the resin composition of claim 1.
